(19) United States
(12) Patent Application Publication
(10) Pub. No.: US 2010/0138724 A1
(43) Pub. Date: Jun. 3, 2010

(54) ADAPTIVE ERROR PROTECTION FOR WIRELESS COMMUNICATIONS

(75) Inventors: Eli Fogel, Herzeliya (IL); Mark Raifel, Ra'anana (IL)

Correspondence Address: TROUTMAN SANDERS LLP;5200 BANK OF AMERICA PLAZA, 600 PEACHTREE STREET, N.E., SUITE 5200, ATLANTA, GA, 30308-2216, US

(73) Assignee: DSP Group Ltd., Herzeliya (IL)

(21) Appl. No.: 12/325,616

(22) Filed: Dec. 1, 2008

(51) Int. Cl. H03M 13/05; G06F 11/10

(52) U.S. Cl. 714/774; 714/776; 714/E11.032

(57) ABSTRACT

A method of error protection for wireless communication of packets of sampled digitized audio data according to a selected communication protocol, comprising: identifying the least significant bits of each sample of audio data encoded in the packets based on the communication protocol used; selectively replacing one or more of the least significant bits with values that enable performing error correction on the rest of the data encoded in the packet; transmitting the altered packet from a transmitting party to a receiving party; using the replaced bits to detect or correct errors in the transmitted packet; wherein said communication protocol uses an ADPCM encoding scheme.

### FIELD OF THE INVENTION

The present invention relates generally to error correction in wireless communication networks, and more specifically to enhancing error correction for standardized wireless transmissions.

### BACKGROUND OF THE INVENTION

Wireless telephony systems are subject to radio-channel noise, which may introduce errors into the communicated data. Generally wireless telephony systems use standard communication protocols that incorporate encodings such as PCM (Pulse Code Modulation), and ADPCM (Adaptive Differential Pulse Code Modulation) to transmit voice data. The residential communication standards such as DECT (Digital Enhanced Cordless Telecommunications), typically offer little error protection. For example the DECT standard specifies TDMA wireless telephony protocol in which each 10 mSec of audio is encoded into packets, each such packet allocated a time slot in a TDMA communication protocol, where the only error protection of the encoded voice is a short CRC. Specifically, when ADPCM G.726/7 is used to encode narrow band (NB) voice, only four bits CRC is provided for each slot of 320 bits. Similarly G.722 uses 640 bits to encode each 10 mSec of voice with only four bits or 32 bits (long slot) for error protection in the voice payload. Such a small amount of protection bits can only allow for low error detection probability per 10 mSec slot and no error correction capability. In case of detected errors, wireless telephony receivers typically use muting or synthesized voice to replace the noise corrupted content to overcome errors. In ADPCM codes such as G.726/7, G.722 an error can have a long range effect since the Vocoder is an adaptive differential and thus previous signal (sometimes long) history is affecting the decoding of present sample Generally to incorporate error correction schemes in wireless telephone systems, more complex devices and more complex coding schemes would be required. These schemes would increase costs and reduce data throughput. Thus it would be desirable to improve error protection without decreasing data throughput and/or requiring more complex devices.

Also, since same device may be used in benign environments with little interference or noise, or in environments with a considerable interference or noise. Accordingly, in an error prone environment a robust protection scheme may be essential for the device to function well, while in benign environment the same scheme may be unnecessary or even undesirable.

The idea of adapting the level of error protection to the radio channel quality has been addressed already e.g. by M. Cooper and S. Schroeder U.S. Pat. No. 6,722,388, by D. Martinez et al, in U.S. Pat. No. 6,009,553, by Agrawell et. Al, in U.S. Pat. No. 6,477,669 and references therein. In the adaptive error protection of the prior art the adaptive error protection mechanism is based on specifically amending bits for error protection, the number of which varies according to channel conditions. For system like DECT, the available bits for error protection is very limited and fixed and thus such error protection augmentation is not possible. Also, the residential systems are very low cost and thus complex and delay prone error protection mechanisms are not affordable.

### SUMMARY OF THE INVENTION

The invention is directed at the error handling of encoded voice in wireless telephony communication. A mechanism for modifying the voice encoded payload by replacing some of its bits by either a message or error protection bits allows adaptation of the system to the radio environment such that the more error prone is the radio environment the deeper is the error protection provided.

The invention uses the terminology “error protection” or the Communication industry terminology “Channel Coding” to represent the bits dedicated for detection and corrections errors induced in the radio channel.

The specific channel coding/error protection that may be applied according to the invention may be any of number of known channel coding schemes commonly used in the communication industry, starting from basic parity bits, CRC, Reed-Solomon code and up to a variety of FEC (Forward Error Correction) codes.

The invention proposes the capability of adaptation of the number of bits to be allocated to the Channel Code. Furthermore, it provides for flexibility in the clustering of channel code visa vi the protected bits. For example, if one bit out of every nibble (4 bits) are allocated to channel coding, the code may be a parity bit per nibble or a CRC(4K,3K) (i.e. Cyclic Redundancy Code applied to every K nibbles using the K less significant bits of these nibbles), A RS (n,k) (i.e. Reed-Solomon Code applied to n bits of the voice payload using k bits of the less significant voice encoded bits) etc.

The invention provides mechanism for assessing the channel quality and choosing the corresponding desired type and level of error protection. Furthermore, the invention presents means for communicating the level of error protection needed, based on the measurement of the channel quality and adaptively changing the protection level in closed loop or open loop schemes, all of these using the less significant bits of the encoded voice. In the open loop case, the invention provides means to test the hypothesis of protection level and apply corresponding decoding scheme. Also, while some wireless standards e.g. DECT provide error detection for entire slots only (typically 10 mSec) the mechanism according to the invention enables localization of the errors within the slot up to a single sample resolution, thus allowing for handling the erroneous samples rather than the erroneous slots.

The present invention resolves the deficiencies of prior art by slightly reducing the voice quality of the encoded voice to provide better error protection. By applying this trade-off process, controlled errors are introduced into the less significant bits while protecting the more significant bits which are more significant for voice quality. The invention also provides methods for using the less significant bits of the encoded voice to convey messages between the communicating parties, including messages regarding the desirable error protection and for probing the channel for its quality so as to establish desirable protection levels.

An aspect of an embodiment of the invention, relates to a method A method of error protection for wireless communication of packets of sampled digitized audio data according to a selected communication protocol, comprising: identifying the least significant bits of each sample of audio data encoded in the packets based on the communication protocol used; selectively replacing one or more of the least significant bits with values that enable performing error correction on the rest of the data encoded in the packet; transmitting the altered packet from a transmitting party to a receiving party; using the replaced bits to detect or correct errors in the received packet; wherein said communication protocol uses an ADPCM encoding scheme.

In some embodiments of the invention the ADPCM encoding scheme is one of the following standards: G.722, or G.727.

In some embodiments of the invention, determining the expected bit error rate level of transmissions at a specific time and setting an error protection level responsive to said determining

In some embodiments of the invention, the number of least significant bits replaced is determined by the error protection level.

In some embodiments of the invention, at least one least significant bit is replaced for each digital sample in each transmission packet of audio data.

In some embodiments of the invention, at least one least significant bit is replaced only for some of the digital samples in each transmission packet of audio data.

In some embodiments of the invention more than one least significant bit is replaced for some or all of the digital samples in each transmission packet of audio data.

In some embodiments of the invention the error protection level is updated upon request by any of the participants in a communication session.

In some embodiments of the invention the error protection level is updated only upon consent of all participants in a communication session.

In some embodiments of the invention some of the least significant bits of the packets are replaced by control message data to transmit control messages.

In some embodiments of the invention determining the bit error rate level of transmission at a specific time is performed by replacing one or more of the least significant bits with predefined bit pattern by the transmitting party and enabling the receiving party to evaluate the channel quality according to estimated number of errors.

In some embodiments of the invention the receiving party determines the error protection applied by the transmitter by applying a maximum likelihood algorithm or alike to the received packet thus identifying the most likely error protection applied by the transmitter to said packet.

In some embodiments of the invention determining the bit error rate level of transmission at a specific time is based on Channel Quality Metric which is a function of at least one of the following parameters:

(a) matching level of the received sync word to known transmitted sync word commonly used;

(b) measured signal strength parameter (RSS) at various times

(c) error indications in protected sections of the signal;

(d) BER estimate based on the channel coding as used in replacing some extended bits of the ADPCM encoded voice signal

(e) based on special messages transmitting with strong channel coding sufficient for the receiver to reconstruct the message and thus determine the level of errors that incurred.

(f) Errors detected in known transmitted message.

In some embodiments of the invention the transmitting party replaces one or more of the least significant bits is responsive to a message that is sent by the receiving party.

In some embodiments of the invention the message that is sent by the receiving party is based on evaluation of channel quality metric performed by the receiving party.

An aspect of an embodiment of the invention, relates to a system for wireless communication, comprising: a first wireless device; a second wireless device that is adapted to communicate with said first wireless device by transmitting and receiving packets with digital audio data samples using a specific communication protocol; an enhanced error correction application installed in said second wireless device and said second wireless device, wherein said enhanced error correction application is adapted to: identify the least significant bits of each sample of audio data encoded in the packets based on the communication protocol used; replace one or more of the least significant bits with values that enable performing error correction on the rest of the data encoded in the packet; transmit the altered packet; use the replaced bits to detect and correct errors in the transmitted packet; and wherein said communication protocol uses an ADPCM encoding scheme.

An aspect of an embodiment of the invention, relates to a method of enhancing error correction for wireless communication transmissions of digitized voice data using ADPCM standard codec G.727 or G.722, by replacing one or more of the less significant data bits (the so called extended bits in the G.727, G.722 standards,) of some of the transmission data, with bits that serve to provide error detection and correction. Additionally the invention relates to performing data bit replacement adaptively as a function of the bit error rate (BER) measured directly or indirectly during the use of the wireless communication channel. Optionally, when transmitting over a noisier communication channel more data bits will be replaced to provide deeper error protection and over a less noisy communication channel less data bits will be replaced or even no data bits will be replaced.

In an exemplary embodiment of the invention, the method is implemented using communication devices that are adapted to support the use of the altered data for error protection, while retaining the ability to work with communication devices using the same protocol that do not support the use of replacing bits to enhance error correction.

In some embodiments of the invention, some of the replaced data bits are used for transmitting control messages between the participants of the wireless communication session to coordinate the level of error protection to implement or for other purposes.

In some embodiments of the invention, the above adaptive error correction scheme is implemented between two devices, for example a base station and a cordless telephone. However it should be noted that the scheme may be implemented when communicating between multiple transmitters and/or multiple receivers.

In some embodiment of the invention, predefined bit patterns or error protection is applied to the less significant bits as a means to probe the channel quality and accordingly to adapt the error protection level to be used

### BRIEF DESCRIPTION OF THE DRAWINGS

The present invention will be understood and better appreciated from the following detailed description taken in conjunction with the drawings. Identical structures, elements or parts, which appear in more than one figure, are generally labeled with the same or similar number in all the figures in which they appear, wherein:

FIG. 1 is a schematic illustration of an enhanced communication system, according to an exemplary embodiment of the invention;

FIG. 2 is a schematic illustration of an enhanced transmission packet based on the G.727 protocol, according to an exemplary embodiment of the invention;

FIG. 3 is a schematic illustration of an enhanced transmission packet based on the G.722 protocol, according to an exemplary embodiment of the invention;

FIG. 4 is a graphic presentation showing voice quality versus BER when applying a few levels of error correction, according to an exemplary embodiment of the invention.

FIG. 5 is an illustration of a synchronous protocol for adaptively changing error protection modes, according to an exemplary embodiment of the invention; and

FIG. 6 is an illustration of an asynchronous protocol for adaptively changing error protection modes, according to an exemplary embodiment of the invention.

FIG. 7 is a block diagram showing the processes that are performed on voice data during transmission and receiving voice data in a system, according to an exemplary embodiment of the invention.

FIG. 8 is a flow chart showing the process of sending and receiving voice data in an open loop structure, according to an exemplary embodiment of the invention.

FIG. 9 is a flow chart showing the process of sending and receiving voice data in a closed loop structure, according to an exemplary embodiment of the invention.

### DETAILED DESCRIPTION

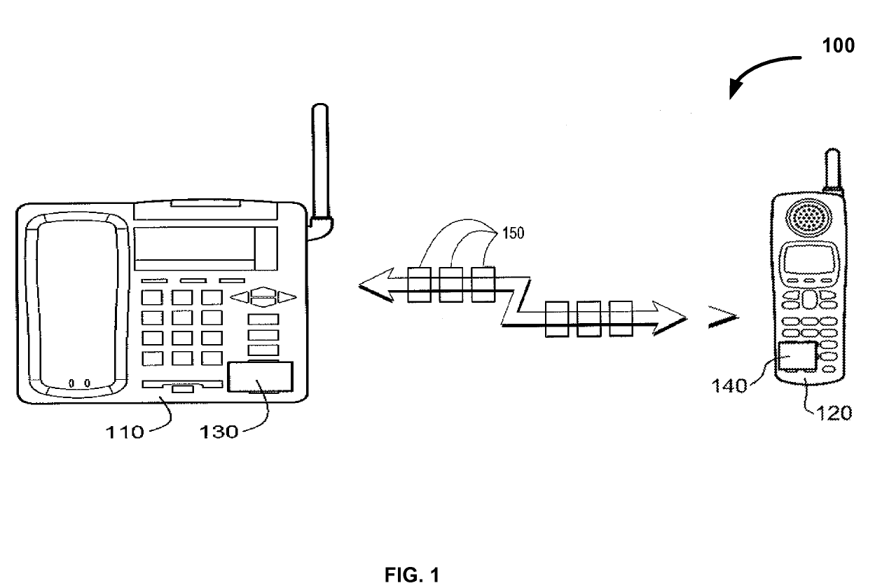

FIG. 1 is a schematic illustration of an enhanced communication system 100, according to an exemplary embodiment of the invention. In an exemplary embodiment of the invention, communication system 100 comprises a base station 110 and a wireless handset 120. Optionally, base station (Fixed Part, FP) 110 and handset (Portable Part, PP) 120 is a wireless telephone system for example a portable telephone conforming to the DECT (digitally enhanced cordless telecommunications) standard. Alternatively, base station 110 may be any type of wireless communication device that transmits and/or receives voice communications wirelessly from another communication device using the DECT standard, for example two wireless handsets 120 communicating with each other.

In an exemplary embodiment of the invention, base station 110 includes an encoding/decoding application 130 which is designed to match an encoding/decoding application 140 on handset 120 so that the transmitted data may be reconstructed correctly. In an exemplary embodiment of the invention, base station 110 and handset 120 wirelessly exchange data packets 150 using a standard form of wireless communications, In an exemplary embodiment of the invention, the transmitted data packets conform to a specific transmission protocol (e.g. G.722, G.727), which defines the layout of the data in the packets and identifies the bits that can be used to serve as error protection (e.g. detection and/or correction packaging).

In an exemplary embodiment of the invention, communication environmental influences may affect the data of packets 150 and introduce errors to the received data. In the DECT standard transmission protocols for the transmission of audio data (e.g. G.722, G.726, and G.727) there is little or no error protection (e.g. only minimal error detection). Optionally, in a noisy environment or if handset 120 is far from base station 110 the bit error rate (BER) increases such that it becomes difficult or impossible to communicate due to errors in the received packets. In an exemplary embodiment of the invention, the least significant bits of the data transmitted that can be manipulated are identified based on the protocol used and some of them are replaced according to a predefined adaptive error correction scheme with values that will allow a more robust error correction. As a result the range for the wireless communications will be enhanced using the same data size and without deviating from the packet structure used by the standard transmission protocol. In a non noisy environment there would not be a noticeable difference if handset 120 was or was not programmed to handle the enhanced packets.

In an exemplary embodiment of the invention, the adaptive error correction scheme performs a tradeoff between accuracy of the received audio data and the correction of random errors in the received audio data signal. Optionally, by using the least significant data bits (or part of the least significant data bits) of a specific protocol as error correction bits, some of the bits will still be correct and some will be wrong. The wrong bits will cause a slight deviation in the accuracy of the audio signal that is reconstructed from them. However random errors to the data signal can cause severe distortion (e.g. by affecting the most significant bits which are more dominant for the audio data) even to the level that the audio signal may be unintelligible. As an example consider an 8 bit binary value representing the number 129, an error to the most significant bit can change its value from 129 to 1, whereas an error to the least significant bit changes its value only from 129 to 128.

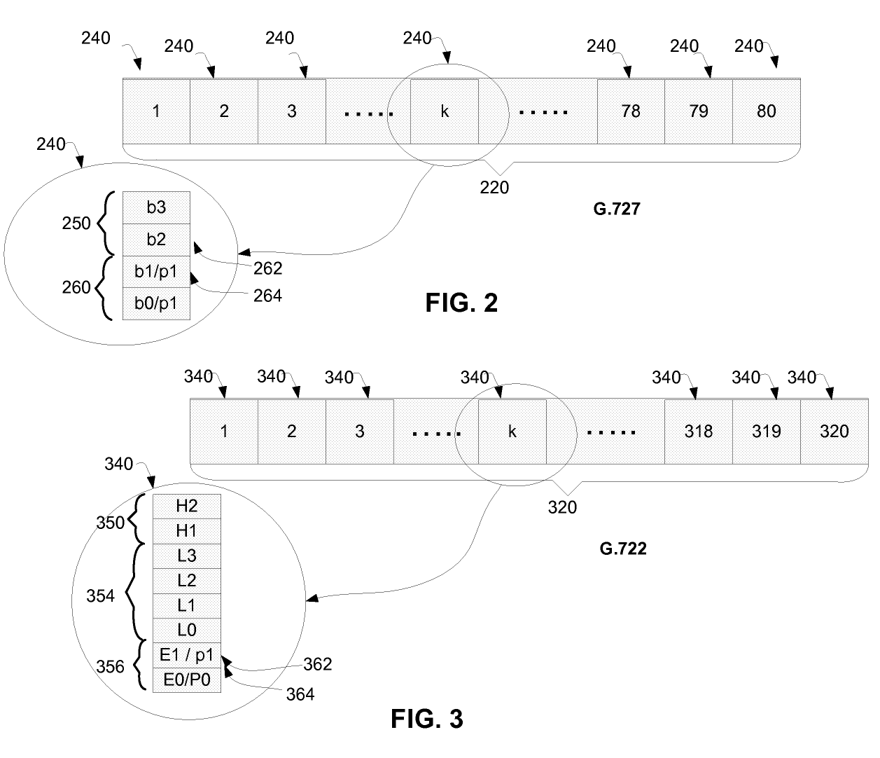

FIG. 2 is a schematic illustration of a transmission packet 210 based on the G.727 encoded voice, according to an exemplary embodiment of the invention. In the conventional G.727 standard narrow band audio (<4 KHz) sampled at 8KSPS is encoded by ADPCM codec using 4 bits per sample to produce 32 KBPS. G.727 encoding may use 3 or 2 primary bits in the ADPCM feedback mechanism (denoted G.727(4,3) G.727(4,2) respectively) The other bits (1, 2 bits respectively), referred to as extended bits are less sensitive to noise. In some embodiments of the invention one or two of the extended bits are replaced with either error protection bits or embedded message to be transmitted from one party to the other or with a probing signal or a combination of the above.

FIG. 2 describes the packet 210 that includes eighty samples 220 (other components of the packet, such as sync, preamble etc. are omitted). Each sample 240 includes two core bits (b3,b2) 250 and two enhanced bits (b1,b0) 260. As shown in FIG. 2, b0 and b1 can be replaced by error protection bits p0, p1 respectively. As shall be further described the number of enhanced bits that are actually used as error protection bits may vary at different times and may also be different for different samples at the same packet.

It should be noted that according to G.727 standard the number of enhanced bits per sample may vary between zero and two, while there is a minimum of two core bits per sample and respectively the enhanced bit (that can be replaced by error protection bits) varies between zero (when using two bits per sample) and two (when using four bits per sample). It should be further noted that while FIG. 2 shows a G.727 protocol that uses four bits per sample, there are other formats of G.727 that use five bits per sample and the present invention is not limited to any specific protocol or format.

FIG. 3 is a schematic illustration of a transmission packet 310 based on the G.722 encoded voice, according to an exemplary embodiment of the invention. In the conventional G.722 standard wide band audio (<8 KHz) sampled at 16KSPS is encoded by ADPCM codec using 8 bits per sample to produce 64 KBPS. G.722 encoding employs sub-band ADPCM coding whereby the lower band (<4 KHz) is encoded by 4 primary bits and 2 extended bits (total of 6 bits) and the high band is ADPCM encoded with 2 bits per sample. FIG. 3 shows one packet 310 containing 320 samples (other components of the packet, such as sync, preamble etc. are omitted). Each sample 340 includes 8 bits, where the upper two bits (h1,h0) 350 belong to the high band, and four bits (b3,b2,b1,b0) 354 belong to the lower band together with two enhanced bits (e1,e0) 356. The two enhanced bits may be replaced by error protection bits p1, p0 respectively. As shall be further described the number of enhanced bits that are actually used as error protection bits may vary at different times and may also be different for different samples at the same packet.

In some embodiments of the invention one or two of the extended bits are replaced with either error protection bits or embedded message to be transmitted from party to the other or with a probing signal or a combination of the above.

In an exemplary embodiment of the invention, the above method may be applied to other variations of encoding, for example ADPCM codes that only include core bits 350 in each sample 340 (e.g. G.726) and no enhanced bits, since the least significant bit/bits of core bits 350 can be replaced to provide error correction with a minimal detrimental affect on the reconstructed signal. Likewise even standards that employ PCM, DPCM or other encoding methods may also be enhanced, for example by using the least significant bit/bits of some or all samples. In some embodiments of the invention, some samples (e.g. 240/340) may contribute more bits for error correction than other samples, for example every odd sample may contribute one bit and every even sample may contribute two bits. Optionally, codes with a varying number of bits in each sample can also be enhanced.

Replacing some or all of the extended bits, results in some degradation of the decoded voice. The more bits are replaced the higher is the degradation. On the other hand undetected errors in the primary bits results in more severe decoded voice quality degradation.

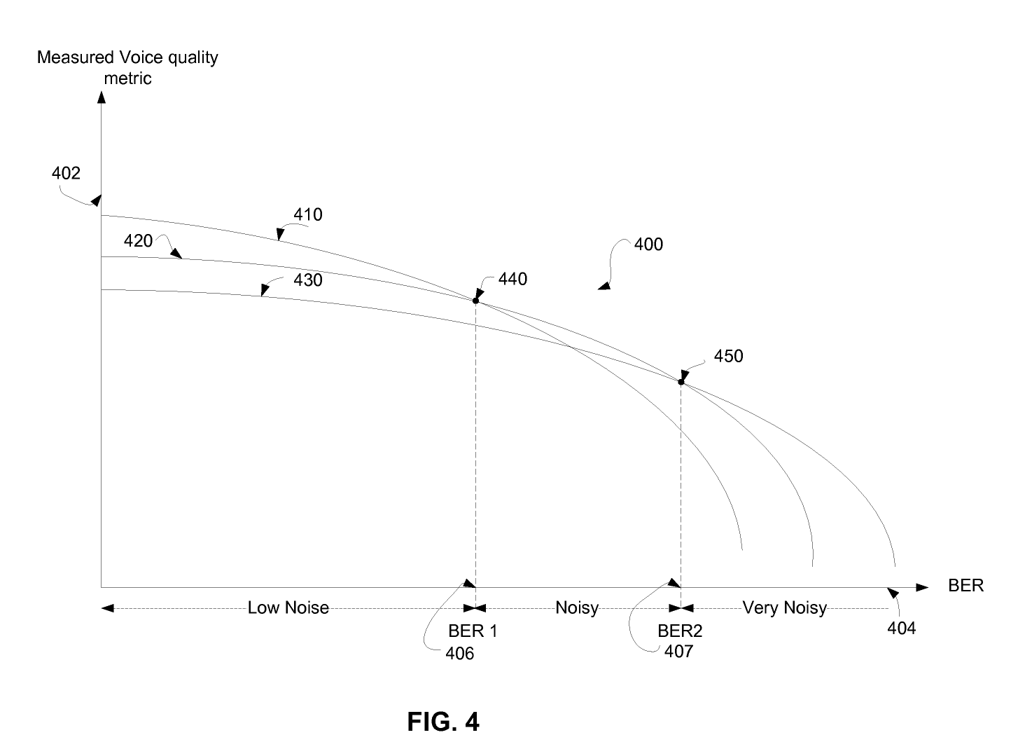

FIG. 4 demonstrates the tradeoff between replacing the extended bits with error protection bits and the degradation due to unresolved errors when no error protection is provided. Since wireless communication channels quality typically varies with the motion of one transceiver relative to the other due to the speaker mobility or may change due to change of the electro magnetic interference environment, it is desirable to adapt the level of protection provided to the radio channel quality.

A graphic presentation of the relation between bit error rate (BER) and decoded voice quality at various level of error protection is shown in FIG. 4. Bit error rate (BER) levels are shown on the horizontal BER axis 404 versus decoded voice quality measure, shown on vertical axis 402. FIG. 4 refers to two values of BER denoted as BER1 406, BER2 407, referring to FIG. 4 there are three levels of noise: No noise (BER<BER1), Noisy (BER1<BER<BER2), Very Noisy (BER2<BER)). FIG. 4 further shows 3 curves 410, 420 and 430 corresponding to three levels of error protection. In an exemplary embodiment of the invention curve 410 represents no bit replacement, i.e. no error protection, curve 420 represents 50% enhanced bit replacement and curve 430 represents 100% enhanced bit replacement. Looking at the curves on FIG. 4 it appears that for noise levels smaller than BER1 406 the optimal choice among the protection schemes is no bit replacement, corresponding to curve is 410, when noise level is between BER1 and BER2 (from intersection point 440 to intersection point 450) the optimal curve (which results with maximal decoded voice quality measurement) among the three curves is 420, i.e. using 50% enhanced bit replacement, and when noise level is higher than BER2 407, curve 430 is the preferred curve (among curves 410, 420 and 430 ), i.e. 100% enhanced bit replacement.

While FIG. 4 shows only three levels of bit replacement, it could be readily understood that various levels of error correction could be employed, for example:
1) No Noise: No bit replacement;
2) Low noisy: Replacing 1 bit out of every second sample;
3) Noisy: Replacing 1 bit out of every sample;
4) Very Noisy: Replacing 1 bit of every odd sample and replacing 2 bits of every even sample;
5) Replacing a selected percentage of each sample, thus replacing more bits of larger sized samples.

Optionally, encoding/decoding applications 130, 140 are programmed to perform an adaptive channel coding scheme wherein the protection level is calculated based on a Channel Quality Metric (e.g. BER) which is function of one or more of the following measured parameters.

1) Matching level of the received sync word to known transmitted sync word commonly used as in a preamble of each slot of TDMA communication scheme.

2) Measured signal strength parameter (RSS) at various times.

3) Error indications in protected sections of the signal, e.g. number of errors as derived from the CRC amended to a field of a DECT slot or CRC amended to the B field of a DECT slot.

4) BER estimate based on the channel coding as used in replacing some extended bits of the ADPCM encoded voice signal

5) Based on special messages transmitting with strong channel coding sufficient for the receiver to reconstruct the message and thus determine the level of errors that incurred.

6) Errors detected in known transmitted message.

In an exemplary embodiment of the invention, encoding/decoding applications 130, 140 apply a decision algorithm, which decides when to increase the protection level and when to decrease it based on the Channel Quality Metric, for example if the BER at the current level exceeds a pre-selected threshold value the protection level is increased to enable reasonable communications. Optionally, the algorithm incorporates a hysteresis algorithm to prevent a state where the error protection level oscillates too frequently.

In some embodiments of the invention, the protection level may jump more than one level at a time to accommodate severe changes in the environment.

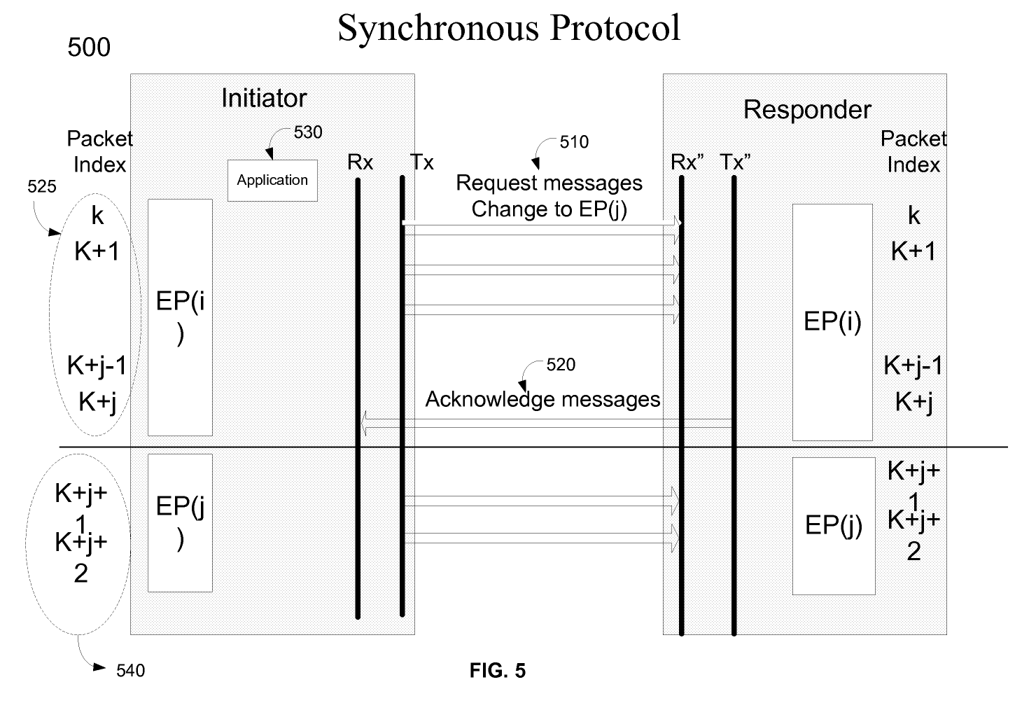

FIG. 5 is an illustration of a synchronous protocol 500 for adaptively changing error protection modes, according to an exemplary embodiment of the invention. In an exemplary embodiment of the invention, one party (e.g. base station 110) is transmitting packets (e.g. K, K+1, . . . K+J−1, K+J) while operating in an error protection level EP(I). At some stage application 530 (marked as 130 in FIG. 1) installed in the first parties device determines that it should increase the error protection level to EP(J), to improve the communication throughput. The first party (initiator) initiates a message 510 to the second party (responder) (e.g. handset 120) to increase the error protection level. Meanwhile the first party keeps using EP(I) and may repeatedly transmit message 510 until it receives acknowledgement 520 from the second party to change to EP(J). The second party begins using EP(J) after sending acknowledgment 520. The first party begins using EP(J) for packets K+J+1,K+J+2 540 after receiving acknowledgment 520 from the second party.

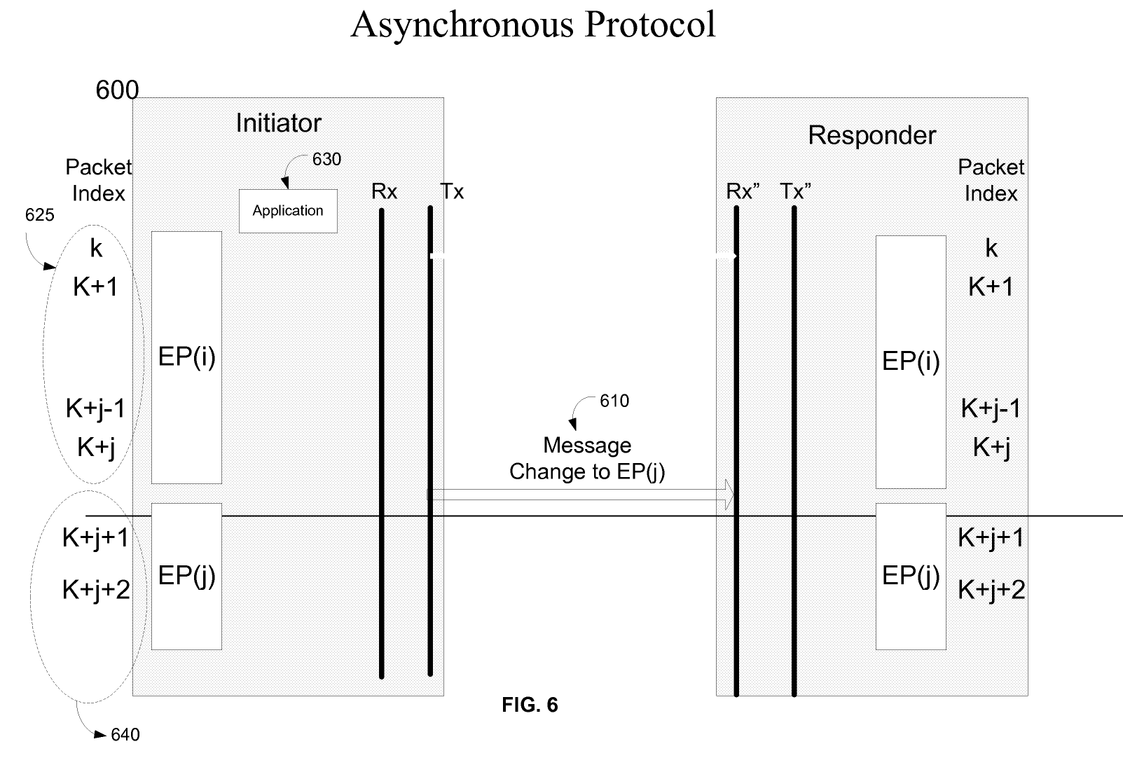

FIG. 6 is an illustration of an asynchronous protocol 600 for adaptively changing error protection modes, according to an exemplary embodiment of the invention. In an exemplary embodiment of the invention, the first party (initiator) (e.g. base station 110) is transmitting packets 625(e.g. K, K+1, . . . K+J−1, K+J) while operating in an error protection level EP(I). At some stage application 630 (marked as 130 in FIG. 1) installed in the first parties device determines that it should increase the error protection level to EP(J), to improve the communication throughput. The first party initiates a message 610 to the second party (e.g. handset 120) to increase the error protection level and immediately updates the error protection scheme it uses to EP(J) for packets K+J+1,K+J+2 640. The second party (responder) begins using EP(J) as soon as it receives message 610.

It should be noted that for both embodiments as shown in FIG. 5 and FIG. 6 the responder may be either the Fixed Part (FF) or the Portable Part (PP).

In another embodiment, the open loop protection level change is performed where the change is implicitly conveyed to the other party by implementing the channel code with no explicit code change message transmitted. The change of code is detected by the receiving party by constantly applying the decoders which match the expected channel codes. If the error rate resulting from the application of the decoder is exceedingly high for the given channel conditions, the receiver infers that the specific code has not been applied. If the error rate measure when applying a specific decoder is compatible with the measured channel conditions, the receiver infers that the specific code has been applied and uses the corresponding error correction/mitigation scheme for that code. An illustrative example: assume that G.727(4,3) is used with either no protection or applying to each sample a code which replaces the extended bit by a parity bit. For each received 80 samples packet, the receiver calculates the parity for each of the 80 samples. If no protection code is applied, the error rate per the parity check will be of the order of 50%. If the parity code has been applied, the error rate so detected will be comparable to the expected BER. Since the communication channels are maintained only for error rate BER of few percent, there is a clear criterion that the receiver may apply to decide that the protection has or has not been applied, e.g. if the number of error>10% of the samples, parity code have not been applied. This method is an example of most likely result algorithms (referred as most likely channel code).

In some protocols the packets include fields (e.g. in the header) which allow the transmission of messages (e.g. a control symbol or control sequence) with every data packet. Optionally, these fields can be used to coordinate between base station 110 and handset 120. Alternatively or additionally, some or all of the least significant bits that are manipulated during transmission by the error correction methods described above may be used to transfer “hidden” messages regarding changing modes of operation, for example the first ten bits may be used to convey messages. Optionally, specific bit sequences may be used as code-words to send a message to initiate the transition to a different mode. Optionally, the code-words are selected with maximum Hamming distance so that they can be recognized even if errors occur during their transmission.

In an exemplary embodiment of the invention, if base station 110 or handset 120 is replaced by a compatible unit, which is not programmed to support the adaptive error correction scheme as described above, communication will still take place without using the enhanced abilities provided by the adaptive error correction scheme since the scheme does not alter the size and layout dictated by the standard protocol.

In some embodiments of the invention, base station 110 may support multiple wireless handsets 120 simultaneously. Optionally, some of the devices may support adaptive error correction and some may not. In some embodiments of the invention, some of the wireless handsets 120 may be communicating while using different error protection levels relative to each other, even if communicating with each other in the same communication session.

Optionally, one direction may conform to one rule and the other direction may conform to a different rule, for example to increase the protection level if either base station 110 or handset 120 request it and to reduce the protection level only if both communicating parties request it.

In some embodiments of the invention, if one party initiates an error protection level change the change will be implemented only after receiving acknowledgment from the other party. Alternatively, error protection may be changed immediately upon sending notification to the other party. Optionally, the time for the change to take effect may be dependent on the decision of the party authorized to initiate the change, for example if either party can initiate the change then the change may take effect immediately upon sending notification to the other party, whereas if consent is required then the initiator must wait to receive acknowledgment from the other party.

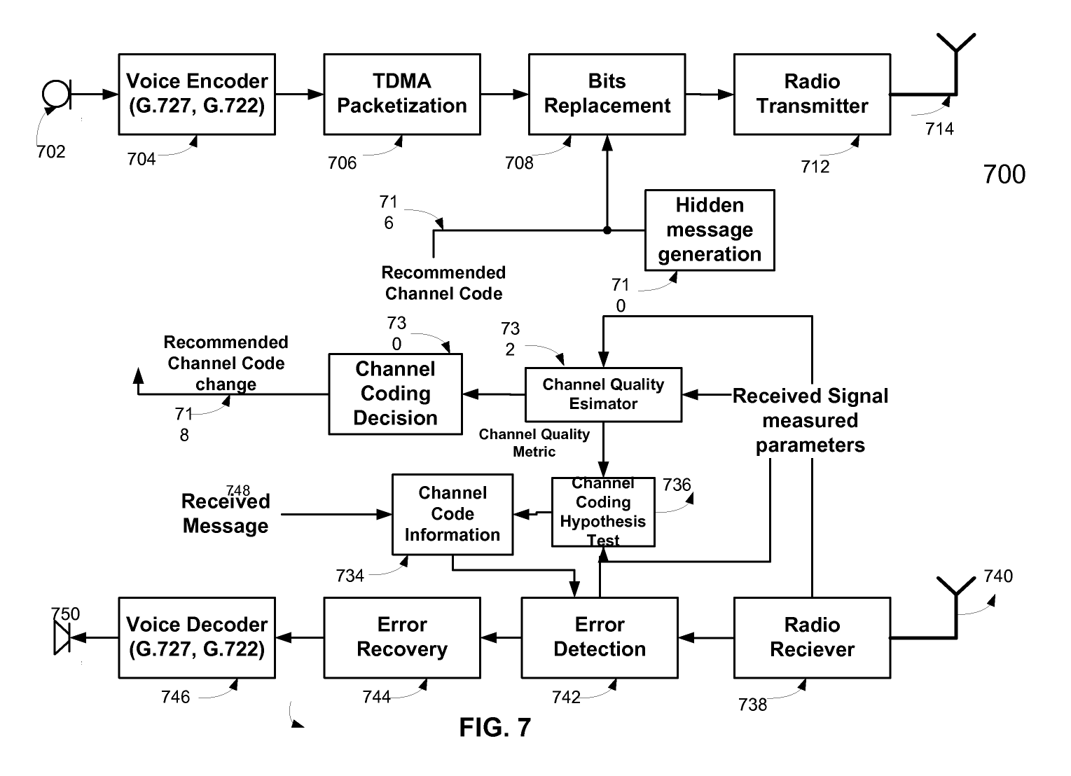

FIG. 7 describes schematically the signal flow from the microphone of one end of the communicating pair, to the speaker of the other party according to a preferred embodiment of the invention. The dashed lined blocks embody the main contribution of this invention. Only those blocks in the signal chain which are essential for the description of the patent are presented while others which are obvious to the skilled in the art are omitted.

The voice samples that are created at the microphone end 702 are encoded by standard ADPCM (G.727 for Narrow Band NB voice, G.722 for wide band WB voice) 704. Every 10 mSec of encoded voice is packetized 706 to be transmitted in a TDMA regime say per the DECT standard. Depending on an estimated radio channel quality metric, a decision is made regarding the level of error protection (“channel code”) to be applied to the encoded speech. The bits replacement (708) is performed according to a policy that may be based on either a hidden message (710), to be transmitted to the other party, or on a recommended channel code (716) that is locally calculated by the transmitting party, optionally based or partially based on recommendation (718) issued by the receiving party.

The error protected packet is transmitted (712) over the air to the other party through antenna (714) and is received by the other party at radio receiver (738) with radio-channel induced errors.

Using the error detection/correction mechanism (742) applicable to the applied channel code, the receiver applies errors recovery mechanism (744) and decodes the ADPCM encoded voice (746), to be introduced into the receiver speaker (750). In addition to the main branch from the antenna to the speaker, the receiver also has a side branch which is used to produce channel quality estimation (732) based on data obtained from the receiver radio and/or on the error detection mechanism (742). In order to detect errors the receiver uses channel code information which may be produced by channel hypothesis test (736) based on channel quality estimator (732) or, when supplied by the other party, the channel code information (734) is provided through received messages (748). This metric may be used locally by the receiving party when it change its role and transmits its voice (bellow related to as “open loop”, or may be conveyed as a message over the radio link to the other party (718) after being calculated by channel coding decision unit (730) to be used in its application of channel code as described above.

In an exemplary embodiment of the invention, protection level change may be decided locally based on the locally calculated quality measure, referred to as Open Loop Adaptive Channel Coding (OLACC)). OLACC implies that the receiver and transmitter are in the same unit and the Channel Quality Metric and channel coding decision are locally canaliculated.

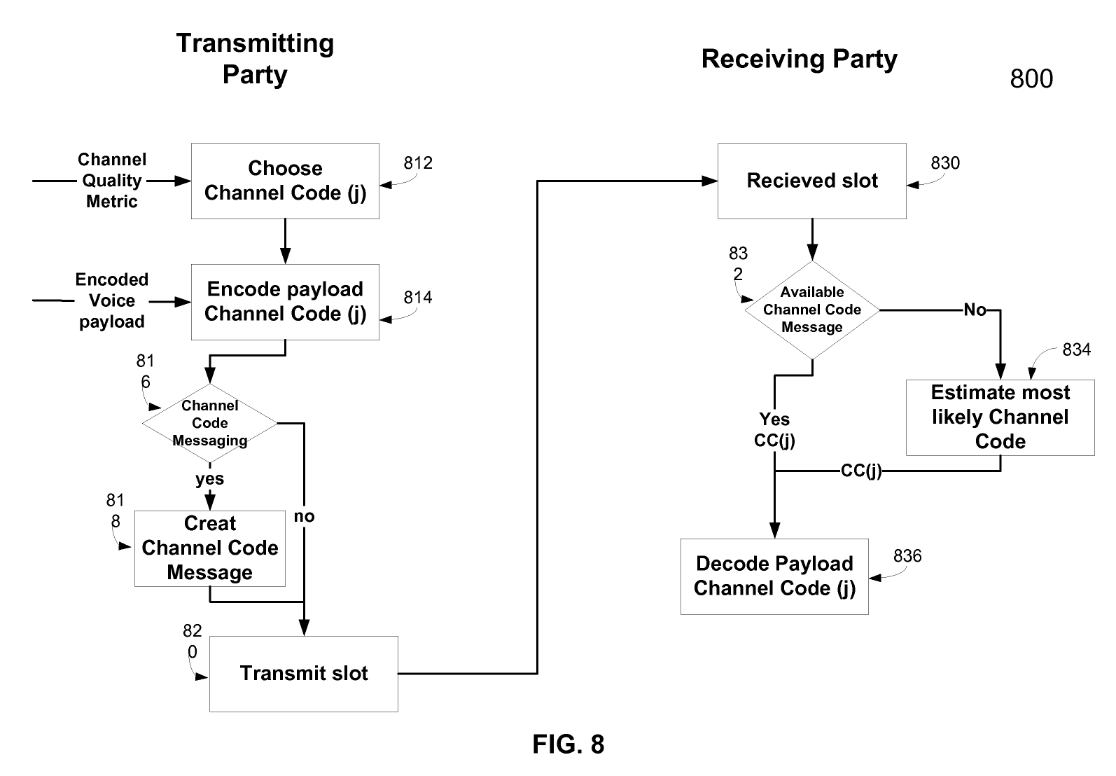

FIG. 8 is a flow chart describing an OLACC system. A transmitting party chooses a channel code (812), encodes the payload by applying the chosen channel code (814). The transmitting party checks if a channel code message is used, if a channel code message is used (816), the transmitting party creates a channel code message (818) and transmits the data slot (820). If a channel code message is not applied the data slot is transmitted directly (820). The receiving party intercepts the data slot (830) and checks if a channel code message is available (832). If a channel code message is not available the receiving party estimates most likely channel code (834) and decodes the payload according to the estimated most likely channel code (836). If channel code message is available, the receiving party decodes the payload by applying the channel code message (836).

The OLACC scheme works well for symmetric channels, i.e. when both parties are suffering from same level and type of channel impairments. Since OLACC is not synchronized between the parties the receiver needs to identify channel coded slots and level of protection so as to apply the relevant decoder.

In an exemplary embodiment, the encoding party sends within the slot preamble an indication of the channel coding scheme being used.

In another exemplary embodiment, the receiving party is constantly running a hypothesis test to identify the channel encoded scheme chosen by the transmitter. For example considers the case of G.727 where either no channel coding is applied or a parity bit replaces the extended bit of each nibble. For reasonable channel quality, applying parity check to uncoded slot will result in approximately 50% “detected errors” while when applied to coded slot will result in error detection commensurate with the expected BER per the Channel Quality measured.

Alternatively, protection level change may be dictated by the receiving party based on its calculated Channel Quality Metric. A request to change the channel coding scheme is conveyed to the other end. Such a scheme is referred to as Closed Loop Adaptive Channel Coding (CLACC). In such case the receiving party will transmit a request to increase or decrease the error protection level one or more levels or specify the type of channel coding it desires for maintaining good voice quality.

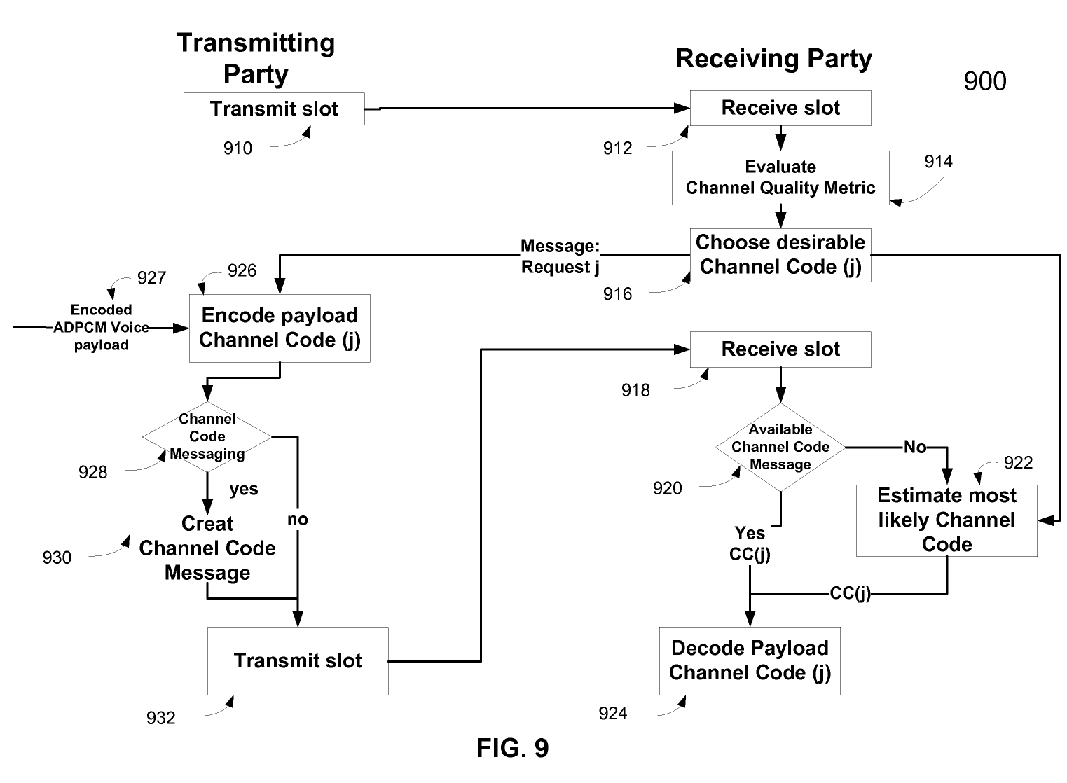

FIG. 9 is a flowchart describing a CLACC, where a transmitting party transmits a slot (910) that is received (912) by a receiving party. The receiving party evaluates the channel quality metric (914) and chooses a desirable channel code (916). The chosen channel code is sent to the transmitting party and is used for encoding payload at the transmitting party (926), the transmitting party than checks if a channel code messaging is performed (928) and if there is a channel code messaging the transmitting party creates a channel code message (930) and transmits a slot to the receiving party (932). If a channel code messaging is not performed in the system, the transmitting party directly transmits a data slot to the receiving party (932). When the transmitted slot is received by the receiving party (918) it checks if there is an available channel code message, if there is no channel code message, the receiving party estimates most likely channel code (922) by using also the information of the desirable channel code that was previously sent to the transmitting party (916). And then the receiving party decodes the payload (924). If there is an available channel code message, the receiving party directly decodes the payload (924) by applying the channel code per the received message.

It should be noted that while some embodiments that were described above referred to a base station communicating with a portable part (PP) (also referred to as handset), it could be readily understood by a person skilled in the art that the invention is not limited to a communication between a fixed part (FP) and a portable part, but is applicable for any type of wireless devices, either FP or PP.

It should be appreciated that the above described methods and apparatus may be varied in many ways, including omitting or adding steps, changing the order of steps and the type of devices used. It should be appreciated that different features may be combined in different ways. In particular, not all the features shown above in a particular embodiment are necessary in every embodiment of the invention. Further combinations of the above features are also considered to be within the scope of some embodiments of the invention.

It will be appreciated by persons skilled in the art that the present invention is not limited to what has been particularly shown and described hereinabove. Rather the scope of the present invention is defined only by the claims, which follow.

1. A method of error protection for wireless communication of packets of sampled digitized audio data according to a selected communication protocol, comprising:
identifying the least significant bits of each sample of audio data encoded in the packets based on the communication protocol used; selectively replacing one or more of the least significant bits with values that enable performing error correction on the rest of the data encoded in the packet;
transmitting the altered packet from a transmitting party to a receiving party;
using the replaced bits to detect or correct errors in the transmitted packet; and
wherein said communication protocol uses an ADPCM encoding scheme.

2. A method according to claim 1, wherein the ADPCM encoding scheme is one of the following standards: G.722, or G.727.

3. A method according to claim 1, further comprising determining the bit error rate level of transmissions at a specific time and setting an error protection level responsive to said determining.

4. A method according to claim 3, wherein the number of least significant bits replaced is determined by the error protection level.

5. A method according to claim 3, wherein at least one least significant bit is replaced for each digital sample in each transmission packet of audio data.

6. A method according to claim 3, wherein at least one least significant bit is replaced only for some of the digital samples in each transmission packet of audio data.

7. A method according to claim 3, wherein more than one least significant bit is replaced for some or all of the digital samples in each transmission packet of audio data.

8. A method according to claim 3, wherein the error protection level is updated upon request by any of the participants in a communication session.

9. A method according to claim 3, wherein the error protection level is updated only upon consent of all participants in a communication session.

10. A method according to claim 1, wherein some of the least significant bits of the packets are replaced by control message data to transmit control messages.

11. A method according to claim 3, wherein determining the bit error rate level of transmission at a specific time is performed by replacing one or more of the least significant bits with predefined bit pattern by the transmitting party and enabling the receiving party to evaluate the channel quality according to estimated number of errors.

12. The method of claim 3, wherein the receiving party determines the error protection applied by the transmitter by applying a maximum likelihood algorithm or alike to the received packet thus identifying the most likely error protection applied by the transmitter to said packet.

13. A method according to claim 3, wherein determining the bit error rate level of transmission at a specific time is based on Channel Quality Metric which is a function of at least one of the following parameters:
(a) matching level of the received sync word to known transmitted sync word commonly used;
(b) measured signal strength parameter (RSS) at various times;
(c) error indications in protected sections of the signal;
(d) BER estimate based on the channel coding as used in replacing some extended bits of the ADPCM encoded voice signal;
(e) based on special messages transmitting with strong channel coding sufficient for the receiver to reconstruct the message and thus determine the level of errors that incurred; and
(f) Errors detected in known transmitted message.

14. A method according to claim 1, wherein the transmitting party replaces one or more of the least significant bits is responsive to a message that is sent by the receiving party.

15. A method according to claim 14, wherein the message that is sent by the receiving party is based on evaluation of channel quality metric performed by the receiving party.

16. A system for wireless communication, comprising:
a first wireless device;
a second wireless device that is adapted to communicate with said first wireless device by transmitting and receiving packets with digital audio data samples using a specific communication protocol;
an enhanced error correction application installed in said second wireless device and said second wireless device, wherein said enhanced error correction application is adapted to:
identify the least significant bits of each sample of audio data encoded in the packets based on the communication protocol used;
replace one or more of the least significant bits with values that enable performing error correction on the rest of the data encoded in the packet;
transmit the altered packet;
use the replaced bits to detect and correct errors in the transmitted packet; and wherein said communication protocol uses an ADPCM encoding scheme.

17. A system according to claim 16, wherein the ADPCM encoding scheme is one of the following standards: G.722, or G.727.

18. A system according to claim 16, wherein the first wireless device is a fixed port (FP) and the second wireless device is a portable part (PP).

19. A system according to claim 16, wherein a wireless device compatible to said first or second wireless device without said installed enhanced error correction application can accept and reconstruct communications from said first or second wireless device even though data bits have been replaced by said first or second wireless device.

20. A system according to claim 16, wherein said first or second wireless device supports more than one communicating wireless device simultaneously.

21. A system according to claim 16, wherein the system includes more than two wireless devices, wherein some of said wireless devices may support said enhanced error correction and some may not simultaneously.
